(19) United States
(12) Patent Application Publication
(10) Pub. No.: US 2016/0005858 A1
(43) Pub. Date: Jan. 7, 2016

(54) LDMOS DEVICE AND RESURF STRUCTURE

(71) Applicant: Episil Technologies Inc., Hsinchu (TW)

(72) Inventors: Shih-Kuei Ma, Hsinchu City (TW); Geng-Tai Ho, Hsinchu City (TW)

(21) Appl. No.: 14/526,517

(22) Filed: Oct. 29, 2014

(30) Foreign Application Priority Data
Jul. 7, 2014 (TW) 103123360

(51) Int. Cl. H01L 29/78; H01L 29/06

(52) U.S. Cl. CPC H01L 29/7818; H01L 29/063

(57) ABSTRACT

A reduced surface field (RESURF) structure and a lateral diffused metal oxide semiconductor (LDMOS) device including the same are provided. The RESURF structure includes a substrate of a first conductivity type, a well region of a second conductivity type, an isolation structure and a PN junction diode. The well region is disposed in the substrate. The isolation structure is disposed on the well region. The PN junction diode is disposed on the isolation structure and configured to reduce the surface field.

### CROSS-REFERENCE TO RELATED APPLICATION

This application claims the priority benefit of Taiwan application serial no. 103123360, filed on Jul. 7, 2014. The entirety of the above-mentioned patent application is hereby incorporated by reference herein and made a part of this specification.

### BACKGROUND OF THE INVENTION

1. Field of Invention

The present invention is related to a semiconductor device, and in particular to a reduced surface field (RESURF) structure and a lateral diffused metal oxide semiconductor (LDMOS) device including the structure.

2. Description of Related Art

In recent years, LDMOS devices have been widely used in all types of power integrated circuits or smart power integrated circuits. Operation of an LDMOS device requires a high breakdown voltage and a low on-state resistance (Ron), thereby increasing the performance of the device. In order to obtain a high breakdown voltage and a low on-state resistance, a so-called RESURF LDMOS device is accordingly developed.

In the convention method, a P-type doped region or a P-top region is implanted in an N-type drift region below a field oxide layer. When a reverse bias voltage is applied to the N-type region and P-type region in the device area, charges in the N-type and P-type regions need to be balanced to achieve a high breakdown voltage. Since the P-type doped region is added, the concentration of the N-type doped drift region must be increased, and thus the on-state resistance can be reduced. However, the conventional method requires complicated steps, so the process cost is higher.

### SUMMARY OF THE INVENTION

Accordingly, the present invention provides a RESURF structure and an LDMOS device including the structure, in which a PN junction diode is disposed on an isolation structure. In such disposition, the step of forming the conventional P-top region can be omitted, and the characteristics of high breakdown voltage and low on-state resistance (Ron) can be achieved.

The present invention provides a lateral diffused metal oxide semiconductor (LDMOS) device including a substrate of a first conductivity type, a first well region of a second conductivity type, a second well region of the first conductivity type, a third well region of the second conductivity type, an isolation structure, source and drain regions of the second conductivity type, a gate and a PN junction diode. The first well region is disposed in the substrate. The second well region is disposed in the substrate and adjacent to the first well region. The third well region is disposed in the first well region. The isolation structure is disposed on the first well region between the second well region and the third well region. The source region is disposed in the second well region. The drain region is disposed in the third well region. The gate is disposed on a portion of the first well region and on a portion of the second well region. The PN junction diode is disposed on the isolation structure.

According to an embodiment of the present invention, the PN junction diode is a polysilicon diode.

According to an embodiment of the present invention, the PN junction diode has a first region, a second region and a third region, the second region is between the first region and the third region, the second area has the first conductivity type, and the first and third regions have opposite conductivity types.

According to an embodiment of the present invention, a doping concentration of the second region is less than a doping concentration of the first region or the third region in the PN junction diode.

According to an embodiment of the present invention, the second region of the PN junction diode and the gate have opposite conductivity types.

According to an embodiment of the present invention, a doping concentration of the second region of the PN junction diode is less than a doping concentration of the gate.

According to an embodiment of the present invention, the first region of the PN junction diode is electrically connected to the source region, and the third region of the PN junction diode is electrically connected to the drain region.

According to an embodiment of the present invention, the LDMOS device further includes a body region of the first conductivity type disposed in the second well region.

According to an embodiment of the present invention, one end of the PN junction diode is electrically connected to the body region, and another end of the PN junction diode is electrically connected to the drain region.

According to an embodiment of the present invention, a width of the PN junction diode is greater than at least ½ of a width of the isolation structure.

According to an embodiment of the present invention, the isolation structure comprises silicon oxide.

According to an embodiment of the present invention, the isolation structure comprises a field oxide structure or a shallow trench isolation structure.

According to an embodiment of the present invention, the first conductivity type is P-type and the second conductivity type is N-type, or the first conductivity type is N-type and the second conductivity type is P-type.

The present invention further provides a reduced surface field (RESURF) structure including a substrate of a first conductivity type, a well region of a second conductivity type, an isolation structure and a PN junction diode. The well region is disposed in the substrate. The isolation structure is disposed on the well region. The PN junction diode is disposed on the isolation structure.

According to an embodiment of the present invention, the PN junction diode is a polysilicon diode.

According to an embodiment of the present invention, the PN junction diode has a first region, a second region and a third region, the second region is between the first region and the third region, the second area has the first conductivity type, and the first and third regions have opposite conductivity types.

According to an embodiment of the present invention, a doping concentration of the second region is less than a doping concentration of the first region or the third region in the PN junction diode.

According to an embodiment of the present invention, one end of the PN junction diode is electrically connected to a source region or a body region, and another end of the PN junction diode is electrically connected to a drain region.

According to an embodiment of the present invention, a width of the PN junction diode is greater than at least ½ of a width of the isolation structure.

According to an embodiment of the present invention, the isolation structure comprises silicon oxide.

In view of the above, in the LDMOS device of the invention, by disposing a PN junction diode on an isolation structure, the achieved effect can be equivalent to the case with a double RESURF technique. The breakdown voltage can be effectively improved, and the on-state resistance (Ron) can be greatly reduced. On the other hand, the step of forming the conventional P-top region can be omitted from the process of fabricating the structure of the invention, so the cost can be significantly reduced, and the competitiveness can be improved.

In order to make the aforementioned and other objects, features and advantages of the present invention comprehensible, a preferred embodiment accompanied with figures is described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a cross-sectional view illustrating a LDMOS device according to an embodiment of the present invention.

FIG. 2 is a graph illustrating an electric field distribution of the LDMOS of FIG. 1 taken along the arrow direction.

FIG. 3 is a cross-sectional view illustrating a LDMOS device according to another embodiment of the present invention.

FIG. 4 is a cross-sectional view illustrating a LDMOS device according to yet another embodiment of the present invention.

### DESCRIPTION OF EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

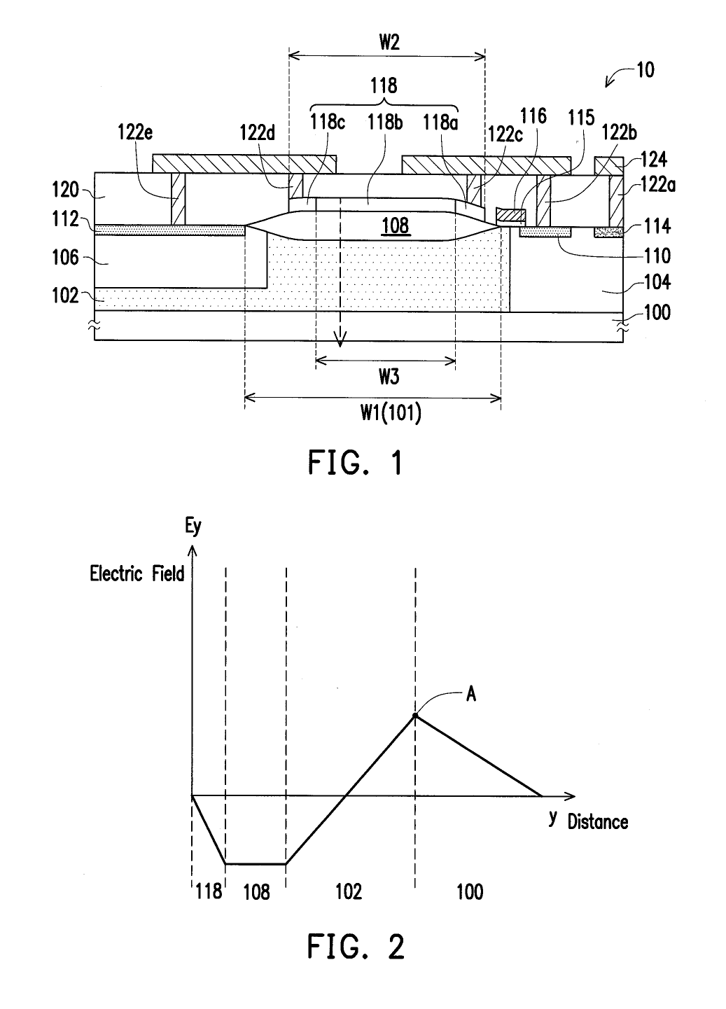

FIG. 1 is a cross-sectional view illustrating a LDMOS device according to an embodiment of the present invention.

Referring to FIG. 1, the LDMOS device 10 of the present invention includes a substrate 100 of a first conductivity type, a first well region 102 of a second conductivity type, a second well region 104 of the first conductivity type, a third well region 106 of the second conductivity type, an isolation structure 108, a source region 110 of the second conductivity type, a drain region 112 of the second conductivity type, a body region 114 of the first conductivity type, a gate oxide layer 115 and a gate 116.

The first conductivity type can be P-type or N-type. When the first conductivity type is P-type, the second conductivity type is N-type. When the first conductivity type is N-type, the second conductivity type is P-type. This embodiment in which the first conductivity type is P-type and the second conductivity type is N-type is provided for illustration purposes, and is not construed as limiting the present invention.

The substrate 100 can be a P-type semiconductor substrate, such as a P-type silicon-containing epitaxial layer. The first well region 102 can be an N-type high-voltage well region disposed in the substrate 100. The second well region 104 can be a P-type well region disposed in the substrate 100 and adjacent to the first well region 102. In this embodiment, the first well region 102 contacts the second well region 104, but the present invention is not limited thereto. In another embodiment (not shown), the first well region 102 and second well region 104 can be separated from each other. The third well region 106 can be an N-type well region disposed in the first well region 102. Besides, the second well region 104 and the third well region 106 are separated by a distance. In an embodiment, the first well region 102 can have a doping concentration of about 1×10¹⁴ to 1×10¹⁷/cm³, the second well region 104 can have a doping concentration of about 1×10¹⁵ to 1×10¹⁷/cm³, and the third well region 106 can have a doping concentration of about 1×10¹⁵ to 1×10¹⁷/cm³.

The isolation structure 108 is disposed on the first well region 102 between the second well region 104 and the third well region 106. The isolation structure 108 includes silicon oxide. The isolation structure 108 can be a field oxide (FOX) structure or a shallow trench isolation (STI) structure.

The source region 110 can be an N-type heavily-doped region disposed in the second well region 104. The drain region 112 can be an N-type heavily-doped region disposed in the third well region 106. In an embodiment, the source region 110 and the drain region 112 can have a doping concentration of about 1×10¹⁹ to 1×10²¹/cm³.

The body region 114 can be a P-type heavily-doped region disposed in the second well region 104. Besides, the body region 114 and the source region 110 are separated by a distance. In an embodiment, the body region 114 can have a doping concentration of about 1×10¹⁷ to 1×10²¹/cm³.

The gate 116 is disposed on a portion of the first well region 102 and on a portion of the second well region 104. In this embodiment, the gate 116 extends to a portion of the isolation structure 108. The gate 116 includes polysilicon. The gate oxide layer 115 is disposed between the gate 116 and the first well region 102 and between the gate 116 and the second well region 104. The gate oxide layer 115 includes silicon oxide. The gate 116 can have an N-type dopant or a P-type dopant. When the gate 116 have an N-type dopant, the gate 116, the source region 110 and the drain region 112 can be doped in the same step. When the gate 116 have a P-type dopant, the gate 116 and the body region 124 can be doped in the same step. In an embodiment, the gate 116 can have a doping concentration of about 1×10¹⁸ to 1×10²¹/cm³.

It is noted that, the LDMOS device 10 of the invention further includes a PN junction diode 118 for replacing the conventional P-top region to reduce the surface field. The PN junction diode 118 is disposed on the isolation structure 108, and is separated from the gate 116 by a distance. In an embodiment, the PN junction diode 118 can be a polysilicon diode. Besides, the PN junction diode 118 can have a first region 118a, a second region 118b and a third region 118c, wherein the second region 118b is disposed between the first region 118a and the third region 118c. In an embodiment, in the PN junction diode 118, the second region 118b has the first conductivity type, and the first region 118a and the third region 118c have opposite conductivity types. More specifically, the central region (i.e. second region 118b) of the PN junction diode 118 has a P-type dopant, and two edge regions (i.e. first region 118a and third region 118c) respectively have an N-type dopant and a P-type dopant.

In this embodiment, the first region 118a has a P-type dopant, and the third region 118c has an N-type dopant, but the present invention is not limited thereto. In another embodiment, the first region 118a can have an N-type dopant, and the third region 118c can have a P-type dopant.

In addition, the central region (i.e. second region 118b) of the PN junction diode 118 has a doping concentration less than that of the edge regions (i.e. first region 118a and third region 118c). In an embodiment, in the PN junction diode 118, the second region 118b can have a P-type doping concentration of about 1×10¹⁴ to 1×10¹⁸/cm³, the first region 118a can have a P-type doping concentration of about 1×10¹⁷ to 1×10²¹/cm³, and the third region 118c can have an N-type doping concentration of about 1×10¹⁹ to 1×10²¹/cm³.

In this embodiment, the central region (i.e. second region 118b) of the PN junction diode 118 and gate 116 have opposite conductivity types, but the present invention is not limited thereto. In another embodiment, upon the customer's requirements or process availability, the central region (i.e. second region 118b) of the PN junction diode 118 and gate 116 can have the same conductivity type. Besides, the second region 118b of the PN junction diode 118 has a doping concentration less than that of the gate 116.

Moreover, in the present invention, the doping concentration and conductivity type of each region of the PN junction diode 118 can be completed simultaneously during the step of forming the N-type source region 110, the step of forming the N-type drain region 112, the step of forming the P-type body region 114 or another implantation step. Thus, additional photomask or process cost is not required.

In this embodiment, although the gate 116 and the PN junction diode 118 are made of polysilicon, they are formed in different process steps. More specifically, when the LDMOS device 10 of the invention has a double-polysilicon structure, the gate 116 with lower resistance can be a first polysilicon layer, while the PN junction diode 118 with higher resistance can be a second polysilicon layer. The first polysilicon layer can be formed prior to the second polysilicon layer.

The said embodiments in which the PN junction diode 118 is a polysilicon diode is provided for illustration purposes, and is not construed as limiting the present invention. In another embodiment, the PN junction diode 118 can be a silicon diode, a germanium diode, a silicon carbide diode or a gallium nitride diode.

The LDMOS device of the invention can further include a first dielectric layer 120, contacts 122a-122e and a first conductive layer 124, as shown in FIG. 1. The first dielectric layer 120 is disposed on the substrate 100 and includes silicon oxide, silicon nitride or silicon oxynitride. The first conductive layer 124 is disposed on the first dielectric layer 120 and includes metal such as aluminium, copper or an alloy thereof The contacts 122a-122e penetrate through the first dielectric layer 120 and include tungsten, titanium, tantalum, aluminium, copper or an alloy thereof.

Besides, the LDMOS device of the invention can further include a second dielectric layer 126, vias 128a-128b and a second conductive layer 130, as shown in FIG. 4. The second dielectric layer 126 is disposed on the first conductive layer 124 and includes silicon oxide, silicon nitride or silicon oxynitride. The second conductive layer 130 is disposed on the second dielectric layer 126 and includes metal such as aluminium, copper or an alloy thereof. The vias 128a-128b penetrate through the second dielectric layer 126 and include tungsten, titanium, tantalum, aluminium, copper or an alloy thereof.

It is noted that in the present invention, one end of the PN junction diode 118 is electrically connected to the source region 110 or the body region 114, and another end of the same is electrically connected to the drain region 112. The drain region 112 is at higher potential, while the source region 110 or the body region 114 is at lower potential. In an embodiment, the source region 110 and the body region 114 are at equal potential, but the present invention is not limited thereto. In another embodiment, the source region 110 and the body region 114 can be at different potentials.

More specifically, in an embodiment, the first region 118a of the PN junction diode 118 is electrically connected to the source region 110 through the contacts 122b/122c and the first conductive layer 124, and the third region 118c of the same is electrically connected to the drain region 112 through the contacts 122d/122e and the first conductive layer 124, as shown in FIG. 1.

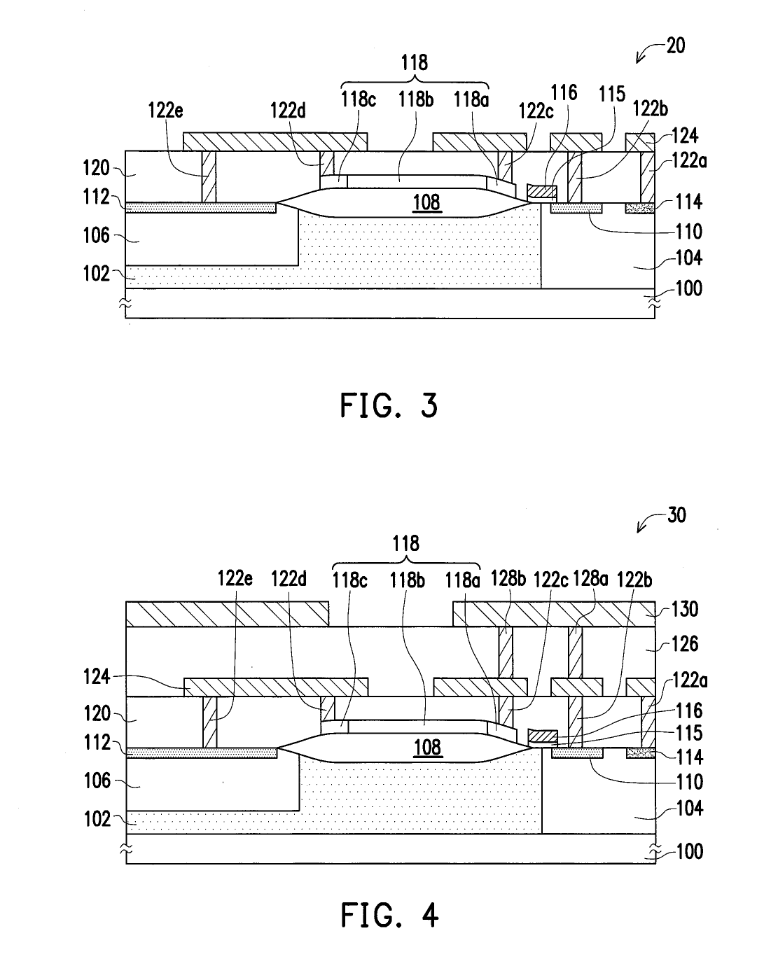

In another embodiment, the first region 118a of the PN junction diode 118 is electrically connected to the body region 114 through the contacts 122a/122c and the first conductive layer 124, and the third region 118c of the same is electrically connected to the drain region 112 through the contacts 122d/122e and the first conductive layer 124, as shown in FIG. 3. In FIG. 3, the first region 118a of the PN junction diode 118 and the body region 114 are electrically connected to each other through a plane routing, so this is not shown in this cross section.

In yet another embodiment, the first region 118a of the PN junction diode 118 is electrically connected to the source region 110 through the contacts 122b/122c, the first conductive layer 124, the vias 128a/128b and the second conductive layer 130, and the third region 118c of the same is electrically connected to the drain region 112 through the contacts 122d/122e and the first conductive layer 124, as shown in FIG. 4.

It is noted that in the LDMOS device of the invention, the PN junction diode 118 is disposed on the isolation structure 108. In such disposition, the PN junction diode 118 can be fully depleted before the breakdown voltage is reached. The concentration of the N-type high-voltage well region (i.e. first well region 102) can be increased due to the space charge effect of the PN junction diode 118, thereby achieving the characteristics of high breakdown voltage and low on-state resistance (Ron).

In order to achieve the said characteristics, the width W2 of the PN junction diode 118 is preferably close to the width W1 of the isolation structure 108 as much as possible. In an embodiment, as shown in FIG. 1, the width W2 of the PN junction diode 118 can be greater than at least ½ or ⅔ of the width W1 of the isolation structure 108. More specifically, the width W3 of the central region (i.e. second region 118b) of the PN junction diode 118 can be greater than at least ½ or ⅔ of the width W1 of the isolation structure 108, so as to effectively reduce the surface field.

FIG. 2 is a graph illustrating an electric field distribution of the LDMOS of FIG. 1 taken along the arrow direction. In the present invention, by sequentially disposing an N-type well region, an isolation structure and a PN junction diode on a substrate, the electric field (along the arrow direction) starts to reduce, and then reaches a constant value, and then gradually increases, and finally drops to zero. The maximum point A of the electric field can be significantly reduced and the lateral electric field can be effectively spread.

Besides, the LDMOS device 10 of the invention also defines a drift region 101 and a RESURF structure located in the drift region 101, as shown in FIG. 1.

Specifically, in the drift region 101, the RESURF structure includes a substrate 100 of a first conductivity type, a first well region 102 of a second conductivity type, an isolation structure 108 and a PN junction diode 118. The first well region 102 is disposed in the substrate 100. The isolation structure 108 is disposed on the first well region 102. The PN junction diode 118 is disposed on the isolation structure 108. Besides, one end of the PN junction diode 118 is electrically connected to a source region 110 or a body region 114, and another end of the same is electrically connected to a drain region 112.

Moreover, in addition to being applied in the LDMOS device, the RESURF structure is also able to be applied in other suitable devices, such as a junction field effect transistor (JFET).

In summary, in the LDMOS device of the invention, a PN junction diode on an isolation structure is configured to replace the conventional P-top region so as to reduce the surface field. In other words, the step of forming the conventional P-top region can be omitted from the process of fabricating the structure of the invention, so the cost can be significantly reduced, and the competitiveness can be improved.

Besides, by sequentially disposing an N-type well region, an isolation structure and a PN junction diode on a substrate, the achieved effect can be equivalent to the case with a double RESURF technique. In such manner, the breakdown voltage can be effectively improved and the on-state resistance (Ron) can be greatly reduced, thereby significantly increasing the performance of the device.

The present invention has been disclosed above in the preferred embodiments, but is not limited to those. It is known to persons skilled in the art that some modifications and innovations may be made without departing from the spirit and scope of the present invention. Therefore, the scope of the present invention should be defined by the following claims.

What is claimed is:

1. A lateral diffused metal oxide semiconductor (LDMOS) device, comprising:
a substrate of a first conductivity type;
a first well region of a second conductivity type, disposed in the substrate;
a second well region of the first conductivity type, disposed in the substrate and adjacent to the first well region;
a third well region of the second conductivity type, disposed in the first well region;
an isolation structure, disposed on the first well region between the second well region and the third well region;
a source region of the second conductivity type, disposed in the second well region;
a drain region of the second conductivity type, disposed in the third well region;
a gate, disposed on a portion of the first well region and on a portion of the second well region; and
a PN junction diode, disposed on the isolation structure.

2. The LDMOS device of claim 1, wherein the PN junction diode is a polysilicon diode.

3. The LDMOS device of claim 1, wherein the PN junction diode has a first region, a second region and a third region, the second region is between the first region and the third region, the second area has the first conductivity type, and the first and third regions have opposite conductivity types.

4. The LDMOS device of claim 3, wherein a doping concentration of the second region is less than a doping concentration of the first region or the third region in the PN junction diode.

5. The LDMOS device of claim 3, wherein the second region of the PN junction diode and the gate have opposite conductivity types.

6. The LDMOS device of claim 3, wherein a doping concentration of the second region of the PN junction diode is less than a doping concentration of the gate.

7. The LDMOS device of claim 3, wherein the first region of the PN junction diode is electrically connected to the source region, and the third region of the PN junction diode is electrically connected to the drain region.

8. The LDMOS device of claim 1, further comprising a body region of the first conductivity type disposed in the second well region.

9. The LDMOS device of claim 8, wherein one end of the PN junction diode is electrically connected to the body region, and another end of the PN junction diode is electrically connected to the drain region.

10. The LDMOS device of claim 1, wherein a width of the PN junction diode is greater than at least ½ of a width of the isolation structure.

11. The LDMOS device of claim 1, wherein the isolation structure comprises silicon oxide.

12. The LDMOS device of claim 1, wherein the isolation structure comprises a field oxide structure or a shallow trench isolation structure.

13. The LDMOS device of claim 1, wherein the first conductivity type is P-type and the second conductivity type is N-type, or the first conductivity type is N-type and the second conductivity type is P-type.

14. A reduced surface field (RESURF) structure, comprising:
a substrate of a first conductivity type;
a well region of a second conductivity type, disposed in the substrate;
an isolation structure, disposed on the well region; and
a PN junction diode, disposed on the isolation structure.

15. The RESURF structure of claim 14, wherein the PN junction diode is a polysilicon diode.

16. The RESURF structure of claim 14, wherein the PN junction diode has a first region, a second region and a third region, the second region is between the first region and the third region, the second area has the first conductivity type, and the first and third regions have opposite conductivity types.

17. The RESURF structure of claim 16, wherein a doping concentration of the second region is less than a doping concentration of the first region or the third region in the PN junction diode.

18. The RESURF structure of claim 14, wherein one end of the PN junction diode is electrically connected to a source region or a body region, and another end of the PN junction diode is electrically connected to a drain region.

19. The RESURF structure of claim 14, wherein a width of the PN junction diode is greater than at least ½ of a width of the isolation structure.

20. The RESURF structure of claim 14, wherein the isolation structure comprises silicon oxide.
